(19) United States
(12) Patent Application Publication
(10) Pub. No.: US 2025/0149475 A1
(43) Pub. Date: May 8, 2025

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: Min Seung JI, Suwon-si (KR); Ha Seob SEONG, Suwon-si (KR); Hyeon Min LEE, Suwon-si (KR); Ae-Nee JANG, Suwon-si (KR)

(73) Assignee: SAMSUNG ELECTRONICS CO., LTD., Suwon-si (KR)

(21) Appl. No.: 18/802,580

(22) Filed: Aug. 13, 2024

(30) Foreign Application Priority Data
Nov. 3, 2023 (KR) 10-2023-0150676

(51) Int. Cl. H01L 23/00; H01L 23/13; H01L 23/48; H01L 23/528; H01L 25/18; H05K 1/18; H10B 80/00

(52) U.S. Cl. CPC H01L 24/05; H01L 23/13; H01L 23/481; H01L 23/5283; H01L 24/02; H01L 24/08; H01L 24/32; H01L 24/73; H01L 24/80; H01L 24/96; H01L 24/97; H01L 25/18; H01L 2224/02331; H01L 2224/02372; H01L 2224/05557; H01L 2224/05647; H01L 2224/08145; H01L 2224/16; H01L 2224/16225; H01L 2224/32225; H01L 2224/73204; H01L 2224/80895; H01L 2224/80896; H01L 2224/96; H01L 2224/97; H01L 2924/1431; H01L 2924/1436; H05K 1/181; H10B 80/00

(57) ABSTRACT

A semiconductor includes a first semiconductor chip, and a second semiconductor chip provided on the first semiconductor chip. The first semiconductor chip includes a first semiconductor substrate including a first front side and a first back side, and a first back-side bonding layer including a first back-side bonding insulating film, and a first back-side bonding pad, wherein the second semiconductor chip includes a second semiconductor substrate including a second front side that faces the first back side and a second back side, and a second front-side bonding layer including a second front-side bonding insulating film bonded to the first back-side bonding insulating film. A side of the first semiconductor chip includes a plurality of first recesses, which are arranged along a vertical direction, and a second recess, which partially exposes a bottom surface of the second front-side bonding layer between the second front-side bonding layer and the first recesses.

### CROSS-REFERENCE TO RELATED APPLICATION

This application claims priority to Korean Patent Application No. 10-2023-0150676, filed on Nov. 3, 2023, in the Korean Intellectual Property Office, the disclosure of which is incorporated by reference herein in its entirety.

### BACKGROUND

### 1. Field

The present disclosure relates to a semiconductor package and a method of fabricating the same, and more particularly, to a semiconductor package including a multi-chip package where a plurality of semiconductor chips is stacked and a method of fabricating the semiconductor package.

### 2. Description of Related Art

With the rapid development of the electronics industry and the diversification of user demands, electronic devices are becoming increasingly miniaturized, lighter, and multi-functional. Similarly, there is a need for semiconductor packages used in electrical devices to be miniaturized, lightweight, and multifunctional. To this end, by integrating several semiconductor chips within a single semiconductor package, it has become possible to significantly reduce the size of the semiconductor package while enabling high capacity and multifunctionality.

Further, to manufacture a multi-chip package where multiple semiconductor chips are stacked, a hybrid bonding method can be used which directly bonds pads to pads and insulating films to insulating films, without using solder bumps. However, the hybrid bonding method has a vulnerability to voids generated from contaminants (such as particles) remaining at bonding interfaces.

### SUMMARY

Example embodiments provide a semiconductor package which may have an improved product reliability and a method of fabricating a semiconductor package which may have an improved product reliability.

According to an aspect of one or more example embodiments, a semiconductor package includes: a first semiconductor chip including: a first semiconductor substrate including a first front side and a first back side that is opposite to the first front side; and a first back-side bonding layer including: a first back-side bonding insulating film on the first back side and a first back-side bonding pad within the first back-side bonding insulating film; a second semiconductor chip on the first semiconductor chip, the second semiconductor chip including: a second semiconductor substrate including a second front side that faces the first back side and a second back side that is opposite to the second front side, a second front-side bonding layer including: a second front-side bonding insulating film on the second front side and bonded to the first back-side bonding insulating film; and a second front-side bonding pad within the second front-side bonding insulating film and bonded to the first back-side bonding pad, wherein a side of the first semiconductor chip includes: a plurality of first recesses arranged along a vertical direction that intersects the first front side and the first back side; and a second recess which partially exposes a bottom surface of the second front-side bonding layer, the second recess being provided between the second front-side bonding layer and the first recesses, and wherein a depth of the second recess is greater than a depth of each of the first recesses in a first horizontal direction that intersects the side of the first semiconductor chip.

According to an aspect of one or more example embodiments, a semiconductor package includes: a semiconductor substrate including: a front side and a back side that is opposite to the front side; a semiconductor device layer on the front side of the semiconductor substrate; a chip wiring layer including: an inter-wiring insulating film covering the semiconductor device layer; and wiring structures within the inter-wiring insulating film and electrically connected to the semiconductor device layer; a front-side bonding layer including: a front-side bonding insulating film covering the chip wiring layer; and a front-side bonding pad within the front-side bonding insulating film and electrically connected to the wiring structures; a back-side bonding layer including: a back-side bonding insulating film on the back side of the semiconductor substrate; and a back-side bonding pad within the back-side bonding insulating film; and a through via penetrating the semiconductor substrate and the semiconductor device layer, and electrically connecting the front-side bonding pad and the back-side bonding pad, wherein a side of the semiconductor substrate includes a plurality of first recesses arranged along a vertical direction that intersects the front side and the back side, wherein a side of the back-side bonding layer includes a second recess, which is between a top surface of the back-side bonding layer and the plurality of first recesses, and wherein a size of the second recess is greater than a size of each of the first recesses.

According to an aspect of one or more example embodiments, a semiconductor package includes: a lower semiconductor chip; and a plurality of semiconductor chips sequentially provided on the lower semiconductor chip, wherein each of the plurality of semiconductor chips includes: a semiconductor substrate including: a front side facing the lower semiconductor chip; and a back side that is opposite to the front side; a semiconductor device layer on the front side of the semiconductor substrate; a chip wiring layer on the semiconductor device layer; a front-side bonding layer including: a front-side bonding insulating film on the chip wiring layer; and a front-side bonding pad within the front-side bonding insulating film; a back-side bonding layer including: a back-side bonding insulating film on the back side of the semiconductor substrate; and a back-side bonding pad within the back-side bonding insulating film; and a through via penetrating the semiconductor substrate and electrically connecting the front-side bonding pad and the back-side bonding pad, wherein a side of each of the plurality of semiconductor chips includes: a plurality of first recesses arranged along a vertical direction that intersects the front side and the back side; and a second recess between a top surface of the back-side bonding layer and the plurality of first recesses, and wherein a size of the second recess is greater than a size of each of the first recesses.

### BRIEF DESCRIPTION OF THE DRAWINGS

The above and other aspects and features will be more apparent from the following description of example embodiments taken in conjunction with the accompanying drawings, in which:

FIG. 1 is a schematic cross-sectional view illustrating a semiconductor package according to one or more example embodiments.

FIG. 2 is an enlarged cross-sectional view of an example of region R1 of FIG. 1, according to one or more example embodiments.

FIGS. 3, 4, 5 and 6 are enlarged cross-sectional views of other examples of region R1 of FIG. 1, according to one or more example embodiments.

FIG. 7 is a cross-sectional view illustrating a semiconductor package according to one or more example embodiments.

FIG. 8 is a schematic cross-sectional view illustrating a semiconductor package according to one or more example embodiments.

FIG. 9 is an enlarged cross-sectional view of an example of region R2 of FIG. 8.

FIGS. 10, 11, 12, 13, 14, 15, 16, 17, 18 and 19 are cross-sectional views illustrating intermediate steps of a method of fabricating a semiconductor package according to one or more example embodiments.

### DETAILED DESCRIPTION

Hereinafter, example embodiments will be described in detail with reference to the accompanying drawings. The same reference numerals are used for the same components in the drawings, and duplicate descriptions thereof are omitted.

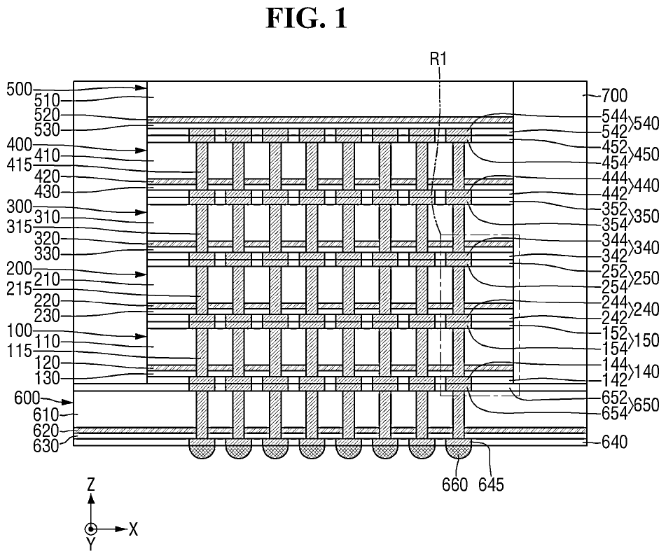

Semiconductor packages according to one or more example embodiments will hereinafter be described with reference to FIGS. 1, 2, 3, 4, 5, 6, 7, 8 and 9.

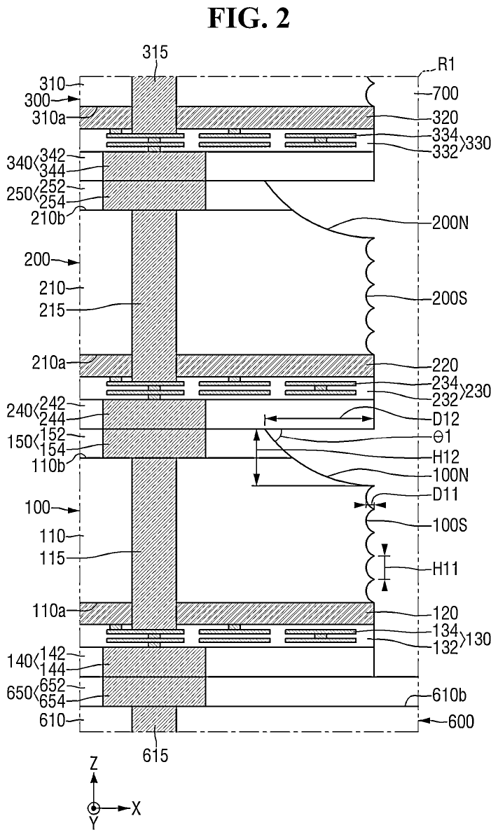

FIG. 1 is a schematic cross-sectional view illustrating a semiconductor package according to one or more example embodiments. FIG. 2 is an enlarged cross-sectional view of an example of region R1 of FIG. 1, according to one or more example embodiments.

Referring to FIGS. 1 and 2, the semiconductor package according to one or more example embodiments may include a plurality of semiconductor chips (100, 200, 300, 400, and 500), a first lower semiconductor chip 600, first connection terminals 660, and a first molding film 700.

Each of the semiconductor chips (100, 200, 300, 400, and 500) may be an integrated circuit (IC) where any number of semiconductor devices, including but not limited to hundreds of thousands or more, are integrated on a single chip. For example, the semiconductor chips (100, 200, 300, 400, and 500) may be logic chips or memory chips. The semiconductor chips (100, 200, 300, 400, and 500) may be sequentially stacked. For example, the semiconductor chips (100, 200, 300, 400, and 500) may include first, second, third, fourth, and fifth semiconductor chips 100, 200, 300, 400, and 500, which are sequentially stacked in a vertical direction Z. The semiconductor chips (100, 200, 300, 400, and 500) may be electrically interconnected.

In one or more example embodiments, the semiconductor chips (100, 200, 300, 400, and 500) may be memory chips of the same type. For example, according to one or more example embodiments, the semiconductor chips (100, 200, 300, 400, and 500) may be volatile memory semiconductor chips, such as dynamic random-access memories (DRAMs) or static random-access memories (SRAMs). According to one or more example embodiments, the semiconductor chips (100, 200, 300, 400, and 500) may be non-volatile memory semiconductor chips, such as phase-change random-access memories (PRAMs), magneto-resistive random-access memories (MRAMs), ferroelectric random-access memories (FeRAMs), or resistive random-access memories (RRAMs).

In one or more example embodiments, some of the semiconductor chips (100, 200, 300, 400, and 500) may be memory chips, and others of the semiconductor chips (100, 200, 300, 400, and 500) may be logic chips. For example, some of the semiconductor chips (100, 200, 300, 400, and 500) may be microprocessors, analog devices, digital signal processors, or application processors, but one or more example embodiments are not limited thereto.

In one or more example embodiments, the widths of the semiconductor chips (100, 200, 300, 400, and 500) may be the same. For example, as illustrated in FIG. 1, sides of the semiconductor chips (100, 200, 300, 400, and 500) that intersect a first horizontal direction X may be arranged on a coplanar surface.

The first semiconductor chip 100 may include a first semiconductor substrate 110, first through vias 115, a first semiconductor device layer 120, a first chip wiring layer 130, a first front-side bonding layer 140, and a first back-side bonding layer 150.

The first semiconductor substrate 110 may be, for example, a bulk silicon or SOI (silicon-on-insulator) substrate. The first semiconductor substrate 110 may be a silicon (Si) substrate or may include other materials such as, for example, silicon germanium, indium antimonide, a lead telluride compound, indium arsenide, indium phosphide, gallium arsenide, or gallium antimonide. Alternatively, according to one or more example embodiments, the first semiconductor substrate 110 may be an epitaxial layer formed on a base substrate.

The first semiconductor substrate 110 may include a first front side 110a and a first back side 110b, which is opposite to the first front side 110a. The first front side 110a may be an active surface where semiconductor devices are formed. For example, the first front side 110a may include conductive regions, such as wells doped with impurities. The first front side 110a may have various device isolation structures, such as shallow trench isolation (STI) structures.

The first semiconductor device layer 120 may be formed on the first front side 110a of the first semiconductor substrate 110. The first semiconductor device layer 120 may include various types of individual devices and/or interlayer insulating films. The individual devices may include various microelectronic devices, such as metal-oxide-semiconductor field-effect transistors (MOSFETs), system large scale integration (LSI), flash memories, DRAMs, SRAMs, electrically erasable programmable read-only memories (EEPROMs), PRAMs, MRAMs, RRAMs, complementary metal-oxide semiconductor (CMOS) imaging sensors (CIS), micro-electro-mechanical systems (MEMSs), active devices, passive devices, etc.

The first chip wiring layer 130 may be stacked on the first semiconductor device layer 120. For example, the first semiconductor device layer 120 may be interposed between the first semiconductor substrate 110 and the first chip wiring layer 130. The first chip wiring layer 130 may include a first inter-wiring insulating film 132, which covers the first semiconductor device layer 120, and first wiring structures 134, which are provided within the first inter-wiring insulating film 132. The first wiring structures 134 may be electrically connected to the individual devices of the first semiconductor device layer 120. The first wiring structures 134 may include multilayer wiring patterns and via patterns connecting the multilayer wiring patterns. The arrangement, number of layers, and quantity of the first wiring structures 134 illustrated according to one or more example embodiments in FIG. 2 are exemplary and not limiting.

The first front-side bonding layer 140 may be stacked on the first chip wiring layer 130. For example, the first chip wiring layer 130 may be interposed between the first semiconductor device layer 120 and the first front-side bonding layer 140. The first front-side bonding layer 140 may include a first front-side bonding insulating film 142, which covers the first chip wiring layer 130, and first front-side bonding pads 144, which are provided within the first front-side bonding insulating film 142. The first front-side bonding pads 144 may be electrically connected to the first wiring structures 134. The bottom surfaces of the first front-side bonding pads 144 may be exposed from the first front-side bonding insulating film 142.

The first back-side bonding layer 150 may be formed on a first back side 110b of the first semiconductor substrate 110. The first back-side bonding layer 150 may include a first back-side bonding insulating film 152, which covers the first back side 110b, and first back-side bonding pads 154, which are provided within the first back-side bonding insulating film 152. The top surfaces of the first back-side bonding pads 154 may be exposed from the first back-side bonding insulating film 152.

The first through vias 115 may extend in the vertical direction Z and may penetrate the first semiconductor substrate 110. The first through vias 115 may electrically connect the first front-side bonding pads 144 and the first back-side bonding pads 154. For example, the first through vias 115 may penetrate the first semiconductor substrate 110 and the first semiconductor device layer 120 and may be connected to the first wiring structures 134. The first front-side bonding pads 144 and the first back-side bonding pads 154 may be electrically connected through the first through vias 115 and the first wiring structures 134.

A side of the first semiconductor chip 100 may include a plurality of first recesses 100S and a second recess 100N. The first recesses 100S and the second recess 100N may each be formed such that at least part of the side of the first semiconductor chip 100 is recessed toward the interior of the first semiconductor chip 100.

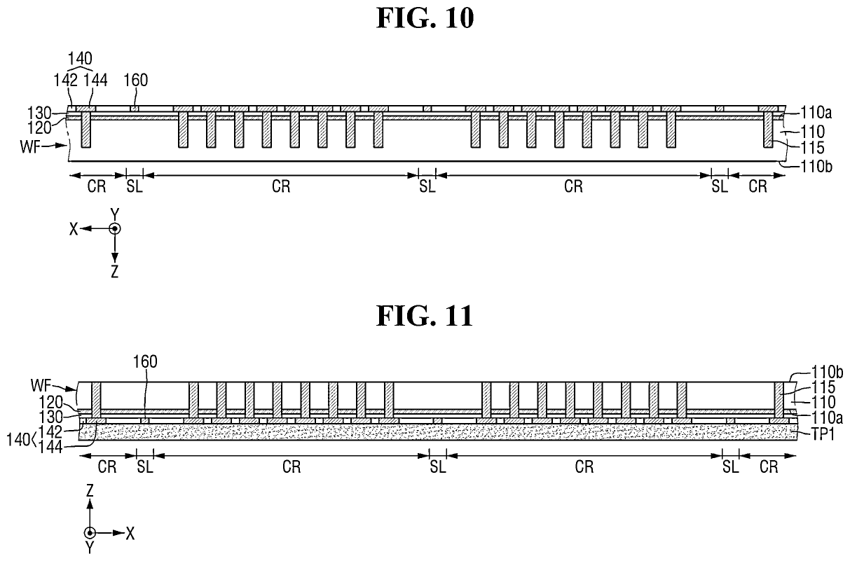

The first recesses 100S may form a repetitive scalloped surface on the side of the first semiconductor chip 100. Specifically, the first recesses 100S may be arranged along the vertical direction Z. Additionally, the first recesses 100S may extend in parallel to one another. For example, the side of the first semiconductor chip 100 that intersects the first horizontal direction X may include a plurality of first recesses 100S extending along a second horizontal direction Y, which intersects the first horizontal direction X. In one or more example embodiments, each of the first recesses 100S may include a concave surface directed toward the interior of the first semiconductor chip 100. The first recesses 100S may be formed during the insulation of the first semiconductor chip 100 from a wafer by a plasma dicing process, which will be described in greater detail below with reference to FIGS. 10, 11, 12, 13, 14, 15, 16, 17, 18 and 19.

At least part of the side of the first semiconductor substrate 110 may include a plurality of first recesses 100S. In one or more example embodiments, the bottoms of the first recesses 100S may be connected to the first front side 110a of the first semiconductor substrate 110.

In one or more example embodiments, the first recesses 100S of the first semiconductor substrate 110 may be more recessed than sides of the first semiconductor device layer 120, the first chip wiring layer 130, and/or the first front-side bonding layer 140. For example, the first recesses 100S may be more recessed toward the interior of the first semiconductor substrate 110 than a plane (e.g., a YZ plane) where the sides of the first semiconductor device layer 120, the first chip wiring layer 130, and/or the first front-side bonding layer 140 extend. In one or more example embodiments, the sides of the first semiconductor device layer 120, the first chip wiring layer 130, and/or the first front-side bonding layer 140 may be arranged on a coplanar surface.

The second recess 100N may be arranged along the vertical direction Z together with the first recesses 100S. The second recess 100N may be formed between the top surface of the first back-side bonding layer 150 and the first recesses 100S. At least part of the side of the first back-side bonding layer 150 may include the second recess 100N. The second recess 100N may connect uppermost parts of the first recesses 100S and the top surface of the first back-side bonding layer 150. The second recess 100N may be formed due to over-etching during a plasma dicing process for the singulation of the first semiconductor chip 100, which will be described below in further detail with reference to FIGS. 10, 11, 12, 13, 14, 15, 16, 17, 18 and 19.

The size of the second recess 100N may be greater than the size of each of the first recesses 100S. For example, in the first horizontal direction X, a second depth D12 of the second recess 100N may be greater than a first depth D11 of each of the first recesses 100S. The first and second depths D11 and D12 may be defined based on, for example, the sides of the first semiconductor device layer 120, the first chip wiring layer 130, and/or the first front-side bonding layer 140. Alternatively, for example, according to one or more example embodiments, in the vertical direction Z, a second height H12 of the second recess 100N may be greater than a first height H11 of each of the first recesses 100S.

The second depth D12 may be, for example, about 20 μm or less. In one or more example embodiments, the second depth D12 may be about 0.5 μm to about 10 μm. The second height H12 may be, for example, about 1 μm or less. In one or more example embodiments, the second height H12 may be about 0.1 μm to about 0.5 μm. Within these ranges, damage to the first semiconductor chip 100 (e.g., cracks) due to the formation of the second recess 100N may be reduced.

In one or more example embodiments, the second recess 100N may include a concave surface. For example, the slope of the second recess 100N relative to the top surface of the first back-side bonding layer 150 may decrease as the second recess 100N extends away from the top surface of the first back-side bonding layer 150.

In one or more example embodiments, the second recess 100N may be formed across the side of the first back-side bonding layer 150 and the side of the first semiconductor substrate 110. For example, at the interface (e.g., the first back side 110b) between the first semiconductor substrate 110 and the first back-side bonding layer 150, a portion of the second recess 100N in the first semiconductor substrate 110 and a portion of the second recess 100N in the first back-side bonding layer 150 may be continuously connected.

The second semiconductor chip 200 may include a second semiconductor substrate 210, second through vias 215, a second semiconductor device layer 220, a second chip wiring layer 230, a second front-side bonding layer 240, and a second back-side bonding layer 250.

The second semiconductor substrate 210 may include a second front side 210a, which faces the first back side 110b, and a second back side 210b, which is opposite to the second front side 210a. The second semiconductor substrate 210 may be the same as or similar to the first semiconductor substrate 110, and thus, a duplicate detailed description thereof will be omitted.

The second semiconductor device layer 220 may be formed on the second front side 210a of the second semiconductor substrate 210. The second semiconductor device layer 220 may be the same as or similar to the first semiconductor device layer 120, and thus, a duplicate detailed description thereof will be omitted.

The second chip wiring layer 230 may be stacked on the second semiconductor device layer 220. The second chip wiring layer 230 may include a second inter-wiring insulating film 232, which covers the second semiconductor device layer 220, and second wiring structures 234, which are provided within the second inter-wiring insulating film 232. The second chip wiring layer 230 may be the same as or similar to the first chip wiring layer 130, and thus, a duplicate detailed description thereof will be omitted.

The second front-side bonding layer 240 may be stacked on the second chip wiring layer 230. The second front-side bonding layer 240 may include a second front-side bonding insulating film 242, which covers the second chip wiring layer 230, and second front-side bonding pads 244, which are provided within the second front-side bonding insulating film 242. The second front-side bonding layer 240 may be the same as or similar to the first front-side bonding layer 140, and thus, a duplicate detailed description thereof will be omitted.

The second back-side bonding layer 250 may be formed on the second back side 210b of the second semiconductor substrate 210. The second back-side bonding layer 250 may include a second back-side bonding insulating film 252, which covers the second back side 210b, and second back-side bonding pads 254, which are provided within the second back-side bonding insulating film 252. The second back-side bonding layer 250 may be the same as or similar to the first back-side bonding layer 150, and thus, a duplicate detailed description thereof will be omitted.

The second through vias 215 may extend in the vertical direction Z and may penetrate the second semiconductor substrate 210. The second through vias 215 may electrically connect the second front-side bonding pads 244 and the second back-side bonding pads 254. The second through vias 215 may be the same as or similar to the first through vias 115, and thus, a duplicate detailed description thereof will be omitted.

A side of the second semiconductor chip 200 may include a plurality of third recesses 200S and a fourth recess 200N. The third recesses 200S and the fourth recess 200N may each be formed such that at least part of the side of the second semiconductor chip 200 is recessed toward the interior of the first semiconductor chip 100. The third recesses 200S may be the same as or similar to the first recesses 100S, and thus, a duplicate detailed description thereof will be omitted. The fourth recess 200N may be the same as or similar to the second recess 100N, and thus, a duplicate detailed description thereof will be omitted.

The first semiconductor chip 100 and the second semiconductor chip 200 may be bonded to each other through the first and second back-side bonding layers 150 and 240. In one or more example embodiments, the second semiconductor chip 200 may be bonded on the first semiconductor chip 100 using a hybrid bonding method. For example, the second front-side bonding insulating film 242 may be directly bonded to the first back-side bonding insulating film 152, and the second front-side bonding pad 244 may be directly bonded to the first back-side bonding pad 154. As an example, if the first back-side bonding pads 154 and the second front-side bonding pads 244 are formed of copper (Cu) and the first back-side bonding insulating film 152 and the second front-side bonding insulating film 242 are formed of an oxide (e.g., SiO₂), the hybrid bonding method may be a copper-oxide hybrid bonding method.

When the first semiconductor chip 100 and the second semiconductor chip 200 are bonded, the second recess 100N of the first semiconductor chip 100 may expose part of the bottom surface of the second front-side bonding layer 240. For example, if the side of the second back-side bonding layer 250 includes the second recess 100N, the width of the top surface of the first back-side bonding layer 150 in the first horizontal direction X may be smaller than the width of the bottom surface of the second front-side bonding layer 240 in the first horizontal direction X.

The third semiconductor chip 300 may include a third semiconductor substrate 310, third through vias 315, a third semiconductor device layer 320, a third chip wiring layer 330, a third front-side bonding layer 340, and a third back-side bonding layer 350.

The fourth semiconductor chip 400 may include a fourth semiconductor substrate 410, fourth through vias 415, a fourth semiconductor device layer 420, a fourth chip wiring layer 430, a fourth front-side bonding layer 440, and a fourth back-side bonding layer 450.

The fifth semiconductor chip 500 may include a fifth semiconductor substrate 510, a fifth semiconductor device layer 520, a fifth chip wiring layer 530, and a fifth front-side bonding layer 540. In one or more example embodiments, the fifth semiconductor chip 500, unlike the first, second, third, and fourth semiconductor chips 100, 200, 300, and 400, may not include through vias and may not include a back-side bonding layer.

The third, fourth, and fifth semiconductor chips 300, 400, and 500 may be the same as or similar to the first semiconductor chip 100 and/or the second semiconductor chip 200, and thus, duplicate detailed descriptions thereof will be omitted.

The first, second, third, fourth, and fifth semiconductor chips 100, 200, 300, 400, and 500 may be sequentially stacked on the first lower semiconductor chip 600. The first lower semiconductor chip 600 may include a sixth semiconductor substrate 610, sixth through vias 615, a sixth semiconductor device layer 620, a sixth chip wiring layer 630, a first chip protective layer 640, a first chip pad 645, and a first upper bonding layer 650.

The sixth semiconductor substrate 610 may include a first top surface 610b, which faces the first front side 110a. The sixth semiconductor substrate 610 may be similar to the first semiconductor substrate 110, and thus, a duplicate detailed description thereof will be omitted.

The sixth semiconductor device layer 620 and the sixth chip wiring layer 630 may be sequentially stacked on the bottom surface of the sixth semiconductor substrate 610. The sixth semiconductor device layer 620 may be similar to the first semiconductor device layer 120, and thus, a duplicate detailed description thereof will be omitted. The sixth chip wiring layer 630 may be similar to the first chip wiring layer 130, and thus, a duplicate detailed description thereof will be omitted.

The first chip protective layer 640 may be stacked on the sixth chip wiring layer 630. The first chip protective layer 640 may cover the sixth chip wiring layer 630. The first chip pads 645 may be formed within the first chip protective layer 640. The bottom surfaces of the first chip pads 645 may be exposed from the first chip protective layer 640.

The first upper bonding layer 650 may be formed on the first top surface 610b of the sixth semiconductor substrate 610. The first upper bonding layer 650 may include a first upper bonding insulating film 652, which covers the first top surface 610b, and first upper bonding pads 654, which are provided within the first upper bonding insulating film 652. The first upper bonding layer 650 may be similar to the first back-side bonding layer 150, and thus, a duplicate detailed description thereof will be omitted.

The sixth through vias 615 may extend in the vertical direction Z and may penetrate the sixth semiconductor substrate 610. The sixth through vias 615 may electrically connect the first chip pads 645 and the first upper bonding pads 654. The sixth through vias 615 may be similar to the first through vias 115, and thus, a duplicate detailed description thereof will be omitted.

The first lower semiconductor chip 600 and the first semiconductor chip 100 may be bonded to each other through the first upper bonding layer 650 and the first front-side bonding layer 140. In one or more example embodiments, the first semiconductor chip 100 may be bonded on the first lower semiconductor chip 600 using a hybrid bonding method. For example, the first front-side bonding insulating film 142 may be directly bonded to the first upper bonding insulating film 652, and the first front-side bonding pads 144 may be directly bonded to the first upper bonding pads 654. As an example, if the first upper bonding pads 654 and the first front-side bonding pads 144 are formed of Cu and the first upper bonding insulating film 652 and the first front-side bonding insulating film 142 are formed of an oxide (e.g., SiO₂), the hybrid bonding method may be a Cu-oxide hybrid bonding method.

In one or more example embodiments, the first lower semiconductor chip 600 and the semiconductor chips (100, 200, 300, 400, and 500), which are stacked on the first lower semiconductor chip 600, may form a stack memory, such as a high bandwidth memory (HBM). For example, the semiconductor chips (100, 200, 300, 400, and 500) may be memory chips, and the first lower semiconductor chip 600 may be a buffer chip. The first lower semiconductor chip 600 may be electrically connected to the semiconductor chips (100, 200, 300, 400, and 500) to transmit signals and/or power from the outside to the semiconductor chips (100, 200, 300, 400, and 500) or vice versa. The first lower semiconductor chip 600 may perform both logic and memory functions by including a plurality of logic elements and a plurality of memory elements. In one or more example embodiments, the first lower semiconductor chip 600 may include only logic elements and may perform only logic functions.

The first connection terminals 660 may be formed below the first lower semiconductor chip 600. The first connection terminals 660 may be electrically connected to the first chip pads 645. For example, the first connection terminals 660 may directly contact the first chip pads 645. The first connection terminals 660 may be, for example, solder balls, bumps, under bump metallurgy (UBM), etc. The first connection terminals 660 may include a metal such as tin (Sn), but one or more example embodiments are not limited thereto.

The first molding film 700 may be formed on the first lower semiconductor chip 600. The first molding film 700 may cover at least parts of the semiconductor chips (100, 200, 300, 400, and 500). For example, the first molding film 700 may cover the top surface of the first lower semiconductor chip 600 and the sides of the semiconductor chips (100, 200, 300, 400, and 500). The first molding film 700 is illustrated as exposing only the top surface of the fifth semiconductor chip 500, but one or more example embodiments are not limited thereto. Alternatively, according to one or more example embodiments, the first molding film 700 may also cover the top surface of the fifth semiconductor chip 500. The first molding film 700 may include an insulating material, for example, an insulating polymer material such as an epoxy molding compound (EMC), but one or more example embodiments are not limited thereto.

As multi-chip packages develop, fine pad pitch and low thermal resistance are desired of semiconductor chips in multi-chip packages. To achieve fine pad pitch and low thermal resistance, a hybrid bonding method, which directly bonds pads to pads and insulating films to insulating films without using solder bumps, will be proposed. However, the hybrid bonding method has a vulnerability to voids generated from contaminants (e.g., particles) remaining at bonding interfaces.

The semiconductor package according to one or more example embodiments can provide a multi-chip package by bonding the semiconductor chips (100, 200, 300, 400, and 500), which are singulated by plasma dicing, using the hybrid bonding method. For example, as described above, the first and second semiconductor chips 100 and 200 may be singulated from the wafer by plasma dicing and may then be stacked using the hybrid bonding method. Plasma dicing, unlike a traditional dicing method, such as blade dicing or laser dicing, causes almost no damage to the wafer, so singulated semiconductor chips may be free from contaminants (e.g., particles). In this manner, voids can be considerably reduced during the bonding of the semiconductor chips (100, 200, 300, 400, and 500) by the hybrid bonding method, and a semiconductor package with an improved product reliability can be provided.

Additionally, the semiconductor package according to one or more example embodiments can more easily expel voids at the interfaces between the semiconductor chips (100, 200, 300, 400, and 500) that are stacked. For example, as described above, the side of the first semiconductor chip 100 may include the second recess 100N, which is formed at the interface between the first and second semiconductor chips 100 and 200. Because the size of the second recess 100N may be greater than the size of each of the first recesses 100S, voids occurring at the interface between the first and second semiconductor chips 100 and 200 can be more easily expelled.

In one or more example embodiments, a first external angle θ1 formed by the top surface of the first back-side bonding layer 150 and the second recess 100N (or at the interface between the first back-side bonding layer 150 and the second front-side bonding layer 240) may be an acute angle. For example, the first external angle θ1 may be about 5° to about 85°. In this example, voids occurring at the interface between the first back-side bonding layer 150 and the second front-side bonding layer 240 can be more effectively expelled.

In one or more example embodiments, the ratio of the second height H12 to the second depth D12 may be, for example, about 0.01 to about 0.5. In one or more example embodiments, the ratio of the second height H12 to the second depth D12 may be about 0.05 to about 0.2. Within these ranges, voids occurring at the interface between the first back-side bonding layer 150 and the second front-side bonding layer 240 can be more effectively expelled.

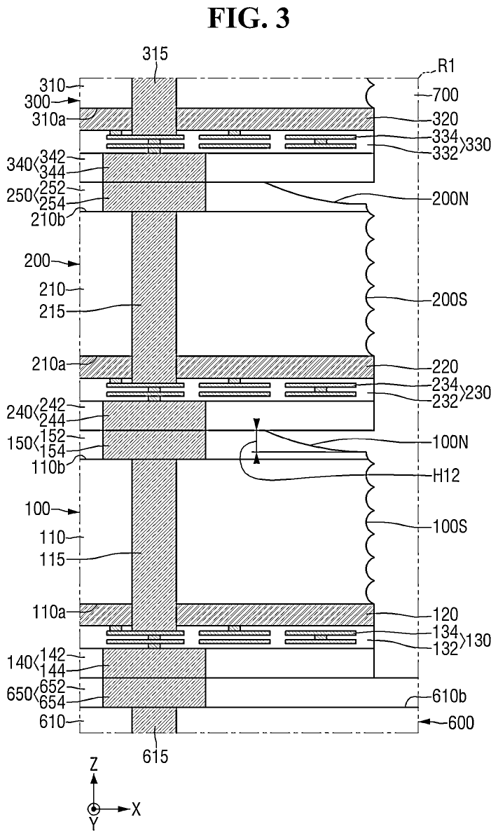

FIGS. 3, 4, 5 and 6 are enlarged cross-sectional views of other examples of region R1 of FIG. 1. For convenience, parts that duplicate the descriptions corresponding to FIGS. 1 and 2 will be briefly explained or omitted.

Referring to FIGS. 1 and 3, the side of the first semiconductor substrate 110 may not include the second recess 100N.

The second recess 100N may only be formed on the side of the first back-side bonding layer 150 and may not extend across the side of the first semiconductor substrate 110. For example, the second height H12 of the second recess 100N may be smaller than the thickness of the first back-side bonding layer 150.

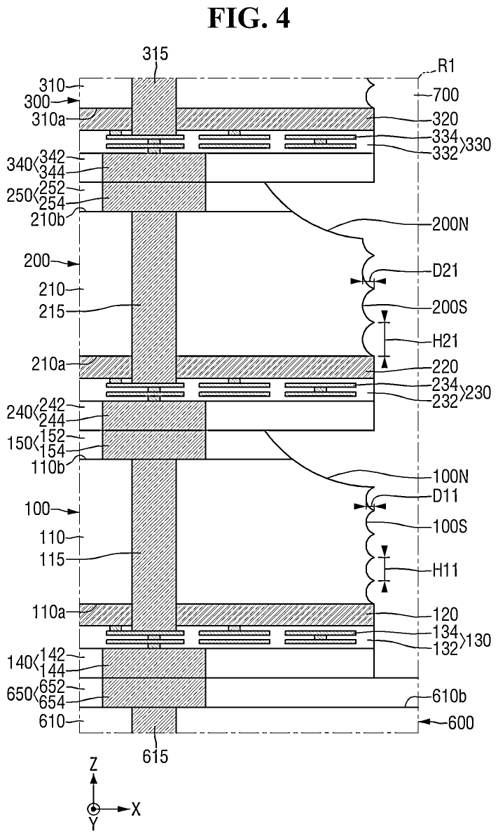

Referring to FIGS. 1 and 4, the size of each of the third recesses 200S may differ from the size of each of the first recesses 100S.

For example, a third depth D21 of each of the third recesses 200S may be greater than the first depth D11 of each of the first recesses 100S. Alternatively, for example, according to one or more example embodiments, a third height H21 of each of the third recesses 200S may be greater than the first height H11 of each of the first recesses 100S. The size of each of the third recesses 200S is illustrated as being greater than the size of each of the first recesses 100S, but one or more example embodiments are not limited thereto. Alternatively, according to one or more example embodiments, the size of each of the third recesses 200S may be smaller in size than the size of each of the first recesses 100S.

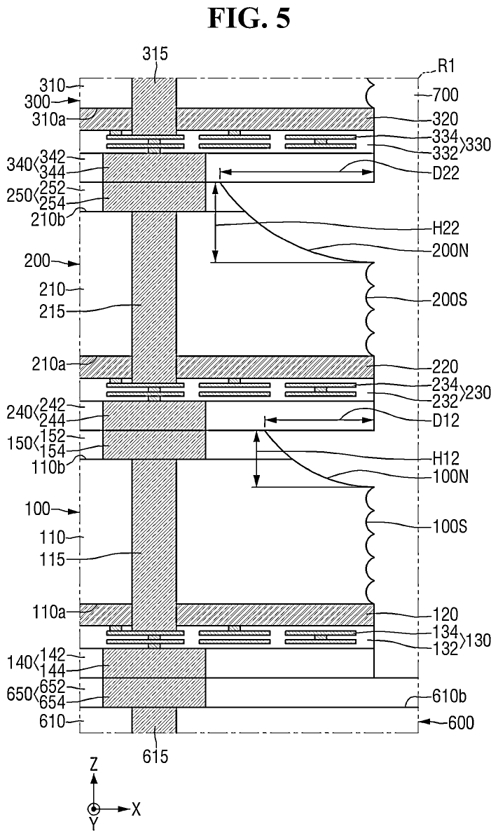

Referring to FIGS. 1 and 5, the size of the fourth recess 200N may differ from the size of the second recess 100N.

For example, a fourth depth D22 of the fourth recess 200N may be greater than the second depth D12 of the second recess 100N. Alternatively, for example, according to one or more example embodiments, a fourth height H22 of the fourth recess 200N may be greater than the second height H12 of the second recess 100N. The size of the fourth recess 200N is illustrated as being greater than the size of the second recess 100N, but one or more example embodiments are not limited thereto. Alternatively, according to one or more example embodiments, the size of the fourth recess 200N may be smaller than the size of the second recess 100N.

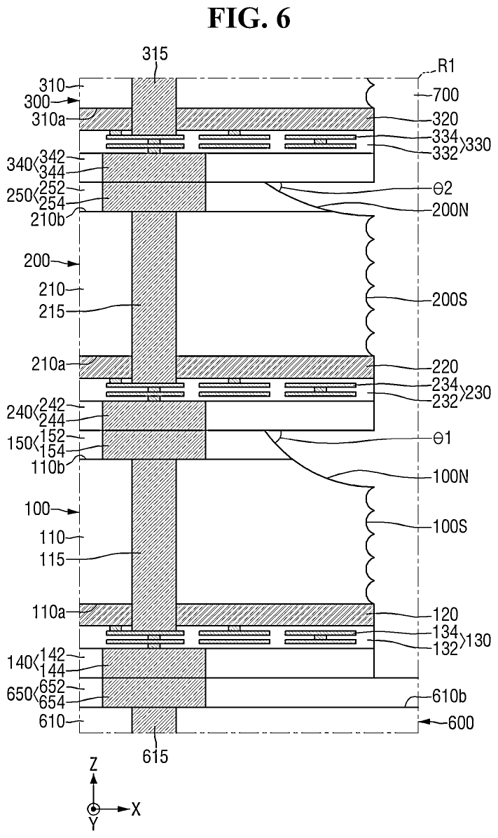

Referring to FIGS. 1 and 6, a second external angle θ2 formed by the top surface of the second back-side bonding layer 250 and the fourth recess 200N may differ from the first external angle θ1 formed by the top surface of the first back-side bonding layer 150 and the second recess 100N.

The second external angle θ2 is illustrated as being smaller than the first external angle θ1, but one or more example embodiments are not limited thereto. Alternatively, according to one or more example embodiments, the second external angle θ2 may be greater than the first external angle θ1.

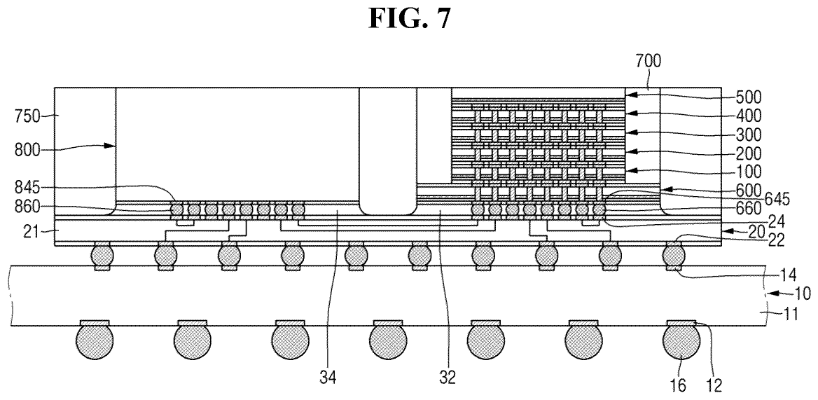

FIG. 7 is a cross-sectional view illustrating a semiconductor package according to one or more example embodiments. For convenience, parts that duplicate the descriptions corresponding to FIGS. 1, 2, 3, 4, 5 and 6 will be briefly explained or omitted.

Referring to FIG. 7, the semiconductor package according to one or more example embodiments may further include a package substrate 10, an interposer 20, a sixth semiconductor chip 800, a first underfill 32, a second underfill 34, and a second molding film 750.

The package substrate 10 may be a substrate for a semiconductor package. For example, the package substrate 10 may be a printed circuit board (PCB). The package substrate 10 may include an insulation core 11, first substrate pads 12, and second substrate pads 14. The first substrate pads 12 and the second substrate pads 14 may be used to electrically connect the package substrate 10 with other components. For example, the first substrate pads 12 may be exposed from the bottom surface of the insulation core 11, and the second substrate pad 14 may be exposed from the top surface of the insulation core 11. The first substrate pads 12 and the second substrate pads 14 may include a metal material such as copper (Cu) or aluminum (Al), but one or more example embodiments are not limited thereto.

According to one or more example embodiments, wiring patterns for electrically connecting the first substrate pads 12 and the second substrate pads 14 may be formed within the insulation core 11. For convenience, the insulation core 11 is illustrated as being a single layer, but one or more example embodiments are not limited thereto. Alternatively, according to one or more example embodiments, the insulation core 11 may be configured as a multilayer, and according to one or more example embodiments multilayer wiring patterns may be formed within the insulation core 11.

The package substrate 10 may be mounted on a mainboard of an electronic device. For example, substrate bumps 16, which are connected to the first substrate pads 12, may be formed. The package substrate 10 may be mounted on a main board of an electronic device through the substrate bumps 16. The package substrate 10 may be a ball grid array (BGA) substrate, but one or more example embodiments are not limited thereto.

The substrate bumps 16 may be, for example, solder bumps, but one or more example embodiments are not limited thereto. The substrate bumps 16 may have various shapes such as a land shape, a ball shape, a pin shape, or a pillar shape. The number, spacing, and arrangement of the substrate bumps 16 are not particularly limited and may vary according to one or more example embodiments.

The interposer 20 may be disposed on the top surface of the package substrate 10. The interposer 20 may be a Si interposer or an organic interposer, but one or more example embodiments are not limited thereto. The interposer 20 may facilitate the connection between the package substrate 10 and semiconductor chips (100, 200, 300, 400, and 500), and may be used to reduce warpage of the semiconductor package according to one or more example embodiments.

The interposer 20 may include a redistribution structure 21, first interposer pads 22, and second interposer pads 24. The first interposer pads 22 and the second interposer pads 24 may be used to electrically connect the interposer 20 with other components. For example, the first interposer pads 22 may be exposed from the bottom surface of the redistribution structure 21, and the second interposer pads 24 may be exposed from the top surface of the redistribution structure 21. The first interposer pads 22 and the second interposer pads 24 may include a metal material such as Cu or aluminum (Al), but one or more example embodiments are not limited thereto.

The interposer 20 may be mounted on the top surface of the package substrate 10. For example, interposer bumps 26 may be formed between the package substrate 10 and the interposer 20. The interposer bumps 26 may connect the second substrate pads 14 and the first interposer pads 22. Consequently, the package substrate 10 and the interposer 20 may be electrically connected.

The interposer bumps 26 may be solder bumps containing a low-melting metal such as tin (Sn) or a Sn alloy, but one or more example embodiments are not limited thereto. The interposer bumps 26 may have various shapes such as a land shape, a ball shape, a pin shape, or a pillar shape. The interposer bumps 26 may be formed as single layers or multilayers. For example, single-layer interposer bumps 26 may include tin-silver (Sn—Ag) solder or Cu. Alternatively, according to one or more example embodiments, multilayer interposer bumps 26 may include copper pillars (Cu pillar) and solder. The number, spacing, and arrangement of the interposer bumps 26 are not particularly limited and may vary.

A first lower semiconductor chip 600 and the semiconductor chips (100, 200, 300, 400, and 500) may be sequentially stacked on the top surface of the interposer 20. The first lower semiconductor chip 600 may be electrically connected to the interposer 20. For example, the first connection terminals 660 may connect the second interposer pads 24 and the first chip pads 645. The first lower semiconductor chip 600 and the semiconductor chips (100, 200, 300, 400, and 500) may be electrically connected to the package substrate 10 through the interposer 20.

The first underfill 32 may be disposed between the interposer 20 and the first lower semiconductor chip 600. The first underfill 32 may fill the space between the interposer 20 and the first lower semiconductor chip 600 and may also cover the first connection terminals 660. The first underfill 32 may include an insulating polymer material such as an EMC, but one or more example embodiments are not limited thereto.

The sixth semiconductor chip 800 may be an IC where any number of semiconductor devices, including but not limited to hundreds to millions of semiconductor devices, are integrated on a single chip. The sixth semiconductor chip 800 may be stacked on the top surface of the interposer 20 to be spaced apart from the first lower semiconductor chip 600 and the semiconductor chips (100, 200, 300, 400, and 500).

In one or more example embodiments, the sixth semiconductor chip 800 may be a logic chip. For example, the sixth semiconductor chip 800 may be an application program (AP) such as a central processing unit (CPU), a graphics processing unit (GPU), a field-programmable gate array (FPGA), a digital signal processor, an encryption processor, a microprocessor, a microcontroller, or an application-specific IC (ASIC), but embodiments are not limited thereto. For example, the sixth semiconductor chip 800 may be an ASIC, such as a GPU, and the first lower semiconductor chip 600 and the semiconductor chips (100, 200, 300, 400, and 500) may be stack memories such as HBMs.

The sixth semiconductor chip 800 may include second chip pads 845. The second chip pads 845 may be used to electrically connect the sixth semiconductor chip 800 with other components. For example, the second chip pads 845 may be exposed from the bottom surface of the sixth semiconductor chip 800.

The sixth semiconductor chip 800 may be mounted on the top surface of the interposer 20. For example, second connection terminals 860 may be formed between the interposer 20 and the sixth semiconductor chip 800. The second connection terminals 860 may connect the second interposer pads 24 and the second chip pads 845. The sixth semiconductor chip 800 may be electrically connected to the first lower semiconductor chip 600, the semiconductor chips (100, 200, 300, 400, and 500), and/or the package substrate 10 through the interposer 20.

The second underfill 34 may be disposed between the interposer 20 and the sixth semiconductor chip 800. The second underfill 34 may fill the space between the interposer 20 and the sixth semiconductor chip 800 and may cover the second connection terminals 860. The second underfill 34 may include an insulating polymer material such as an EMC, but embodiments are not limited thereto.

The second molding film 750 may be formed on the interposer 20. The second molding film 750 may cover the semiconductor chips (100, 200, 300, 400, and 500), the first lower semiconductor chip 600, and the sixth semiconductor chip 800. For example, the second molding film 750 may cover the top surface of the interposer 20, sides of each of the semiconductor chips (100, 200, 300, 400, and 500), sides of the first lower semiconductor chip 600, and sides of the sixth semiconductor chip 800. The second molding film 750 is illustrated as exposing only the top surfaces of the fifth and sixth semiconductor chips 500 and 800, but one or more example embodiments are not limited thereto. Alternatively, according to one or more example embodiments, the second molding film 750 may also cover the top surfaces of the fifth and sixth semiconductor chips 500 and 800. The second molding film 750 may include an insulating material, for example, an insulating polymer material such as an EMC, but embodiments are not limited thereto.

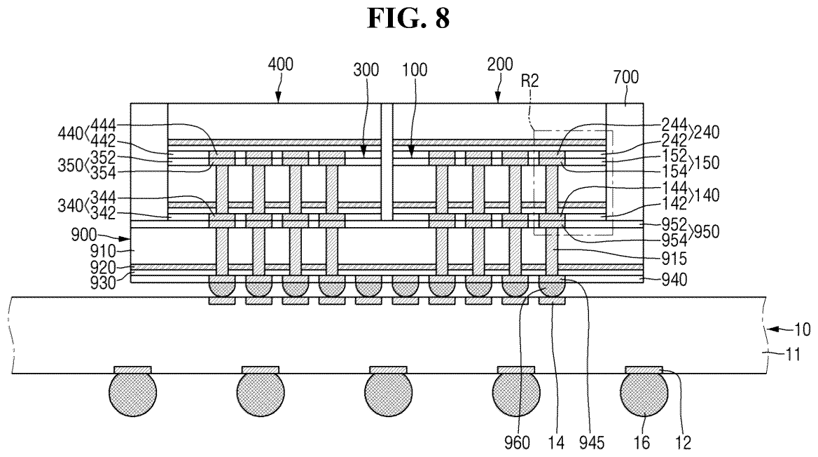

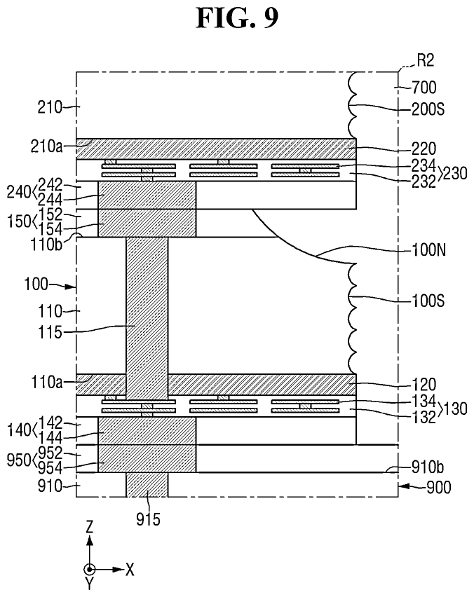

FIG. 8 is a schematic cross-sectional view illustrating a semiconductor package according to one or more example embodiments. FIG. 9 is an enlarged cross-sectional view of an example of region R2 of FIG. 8. For convenience, parts that duplicate the descriptions corresponding to FIGS. 1, 2, 3, 4, 5, 6 and 7 will be briefly explained or omitted.

Referring to FIGS. 8 and 9, the semiconductor package according to one or more example embodiments may further include a package substrate 10, a second lower semiconductor chip 900, and third connection terminals 960.

The second lower semiconductor chip 900 may be stacked on the top surface of the package substrate 10. Semiconductor chips (100, 200, 300, and 400) may be stacked on the second lower semiconductor chip 900. The second lower semiconductor chip 900 may include a seventh semiconductor substrate 910, seventh through vias 915, a seventh semiconductor device layer 920, a seventh chip wiring layer 930, a second chip protective layer 940, third chip pads 945, and a second upper bonding layer 950.

The seventh semiconductor substrate 910 may include a second top surface 910b, which faces a first front side 110a. The seventh semiconductor substrate 910 may be similar to a first semiconductor substrate 110, and thus, a duplicate detailed description thereof will be omitted.

The seventh semiconductor device layer 920 and the seventh chip wiring layer 930 may be sequentially stacked on the bottom surface of the seventh semiconductor substrate 910. The seventh semiconductor device layer 920 may be similar to a first semiconductor device layer 120, and thus, a duplicate detailed description thereof will be omitted. The seventh chip wiring layer 930 may be similar to a first chip wiring layer 130, and thus, a duplicate detailed description thereof will be omitted.

The second chip protective layer 940 may be stacked on the seventh chip wiring layer 930. The second chip protective layer 940 may cover the seventh chip wiring layer 930. The third chip pads 945 may be formed within the second chip protective layer 940. The bottom surfaces of the third chip pads 945 may be exposed from the second chip protective layer 940.

The second upper bonding layer 950 may be formed on the second top surface 910b of the seventh semiconductor substrate 910. The second upper bonding layer 950 may include a second upper bonding insulating film 952, which covers the second top surface 910b, and second upper bonding pads 954, which are provided within the second upper bonding insulating film 952. The second upper bonding layer 950 may be similar to the second back-side bonding layer 250, and thus, a duplicate detailed description thereof will be omitted.

The seventh through vias 915 may extend in a vertical direction Z and may penetrate the seventh semiconductor substrate 910. The seventh through vias 915 may electrically connect the third chip pads 945 and the second upper bonding pads 954. The seventh through-vias 915 may be similar to first through vias 115, and thus, a duplicate detailed description thereof will be omitted.

The second lower semiconductor chip 900 and a first semiconductor chip 100 may be bonded to each other through the second upper bonding layer 950 and a first front-side bonding layer 140. In one or more example embodiments, the first semiconductor chip 100 may be bonded to the second lower semiconductor chip 900 using a hybrid bonding method. For example, a first front-side bonding insulating film 142 may be directly bonded to the second upper bonding insulating film 952, and first front-side bonding pads 144 may be directly bonded to the second upper bonding pads 954. For example, if the second upper bonding pads 954 and the first front-side bonding pads 144 are formed of Cu and the second upper bonding insulating film 952 and the first front-side bonding insulating film 142 are formed of an oxide (for example, SiO₂), the hybrid bonding method may be a Cu-oxide hybrid bonding method.

In one or more example embodiments, the second lower semiconductor chip 900 may be a logic chip. For example, the second lower semiconductor chip 900 may be an application processor (AP) such as CPU, a GPU, an FPGA, a digital signal processor, an encryption processor, a microprocessor, a microcontroller, or an ASIC, but embodiments are not limited thereto. For example, according to one or more example embodiments, the second lower semiconductor chip 900 may be an ASIC such as a GPU, and the first lower semiconductor chip 600 and the semiconductor chips (100, 200, 300, and 400) may be memory chips.

In one or more example embodiments, the first semiconductor chip 100 and a second semiconductor chip 200 may be sequentially stacked on the second lower semiconductor chip 900, and third and fourth semiconductor chips 300 and 400 may be sequentially stacked on the second lower semiconductor chip 900 to be spaced apart from the first and second semiconductor chips 100 and 200.

The third connection terminals 960 may be formed below the second lower semiconductor chip 900. The third connection terminals 960 may be electrically connected to the third chip pads 945. For example, the third connection terminals 960 may be in direct contact with the third chip pads 945. The third connection terminals 960 may be, for example, solder balls, bumps, or UBM. The third connection terminals 960 may include a metal such as Sn, but embodiments are not limited thereto.

A method of fabricating a semiconductor package according to one or more example embodiments will hereinafter be described with reference to FIGS. 1, 2, 3, 4, 5, 6, 7, 8, 9, 10, 11, 12, 13, 14, 15, 16, 17, 18 and 19.

FIGS. 10, 11, 12, 13, 14, 15, 16, 17, 18 and 19 are cross-sectional views illustrating intermediate steps of a method of fabricating a semiconductor package according to one or more example embodiments. For convenience, parts that duplicate the descriptions corresponding to FIGS. 1, 2, 3, 4, 5, 6, 7, 8 and 9 will be briefly explained or omitted.

Referring to FIG. 10, according to one or more example embodiments, a wafer WF is provided.

The wafer WF may include a plurality of chip regions CR and scribe lane regions SL between the chip regions CR. Various types of individual devices may be formed within each of the chip regions CR. The scribe lane regions SL may surround the chip regions CR. For example, the scribe lane regions SL may be in the form of straight lanes having a predetermined width. The chip regions CR may be separated from one another by performing a die sawing process along the scribe lane regions SL.

The wafer WF may include a first semiconductor substrate 110, first through vias 115, a first semiconductor device layer 120, a first chip wiring layer 130, a first front-side bonding layer 140, and item patterns 160. The first semiconductor substrate 110 may include a first front side 110a and a first back side 110b, which is opposite to the first front side 110a. The first semiconductor device layer 120, the first chip wiring layer 130, and the first front-side bonding layer 140 may be sequentially stacked on the first front side 110a of the first semiconductor substrate 110. The first front-side bonding layer 140 may include a first front-side bonding insulating film 142 and first front-side bonding pads 144. At least parts of the first through vias 115 may be formed within the first semiconductor substrate 110. The first through vias 115 may extend in a vertical direction Z and may be connected to the first front-side bonding pads 144. In one or more example embodiments, the first through vias 115 may penetrate the first front side 110a and may be spaced apart from the first back side 110b.

Item patterns 160 may be formed on the first chip wiring layer 130. The item patterns 160 may be disposed within the scribe lane regions SL. For example, the item patterns 160 may be formed within the first front-side bonding insulating film 142 in the scribe lane regions SL. The item patterns 160 may include, for example, test element group (TEG) modules, alignment keys, and/or metrology & inspection (MI) elements, but embodiments are not limited thereto.

Referring to FIG. 11, according to one or more example embodiments, a thinning process may be performed on the first back side 110b of the first semiconductor substrate 110.

For example, a first tape TP1 may be attached to the first front-side bonding layer 140. The first tape TP1 may be a wafer tape, a die attach film (DAF), or a stack of a wafer tape and a DAF, but embodiments are not limited thereto. Thereafter, the wafer WF with the first tape TP1 attached thereto may be flipped, exposing the first back side 110b of the first semiconductor substrate 110, and a back-grinding process may be performed on the first back side 110b. The back-grinding process may reduce the thickness of the first semiconductor substrate 110 and may expose the first through vias 115 from the first back side 110b.

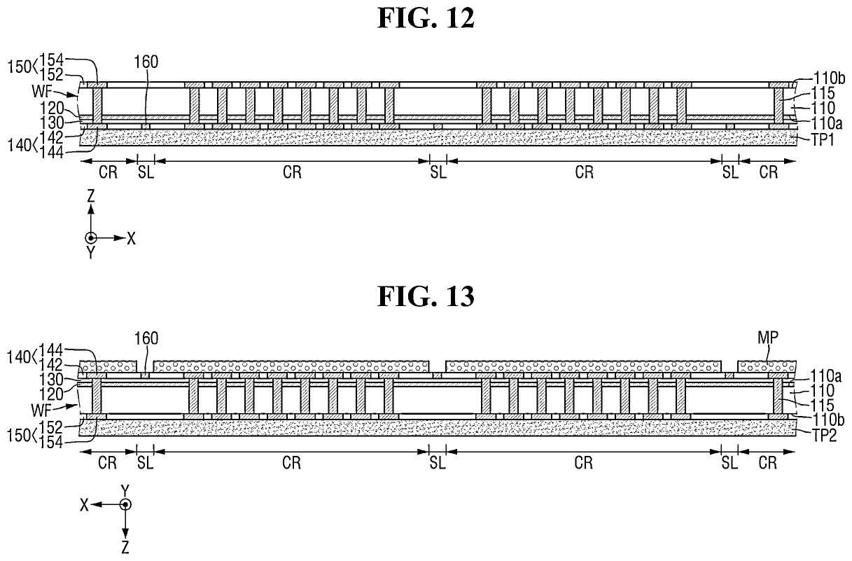

Referring to FIG. 12, according to one or more example embodiments, a first back-side bonding layer 150 is formed on the first back side 110b of the first semiconductor substrate 110.

The first back-side bonding layer 150 may include a first back-side bonding insulating film 152 and first back-side bonding pads 154. The first back-side bonding pads 154 may be connected to the first through vias 115. The first front-side bonding pads 144 and the first back-side bonding pads 154 may be electrically connected through the first through vias 115.

Referring to FIG. 13, according to one or more example embodiments, mask patterns MP may be formed on the first front-side bonding layer 140.

For example, a second tape TP2 may be attached to the first back-side bonding layer 150. The second tape TP2 may be a wafer tape, a DAF, or a stack of a wafer tape and a DAF, but embodiments are not limited thereto. Thereafter, the wafer WF with the second tape TP2 attached thereto may be flipped, exposing the first front-side bonding layer 140. Then, the mask patterns MP may be formed on the first front-side bonding layer 140. The mask patterns MP may cover the first front-side bonding layer 140 in the chip regions CR and may expose the first front-side bonding layer 140 and the item patterns 160 in the scribe lane regions SL. The mask patterns MP may include a material such as photoresist, but one or more example embodiments are not limited thereto.

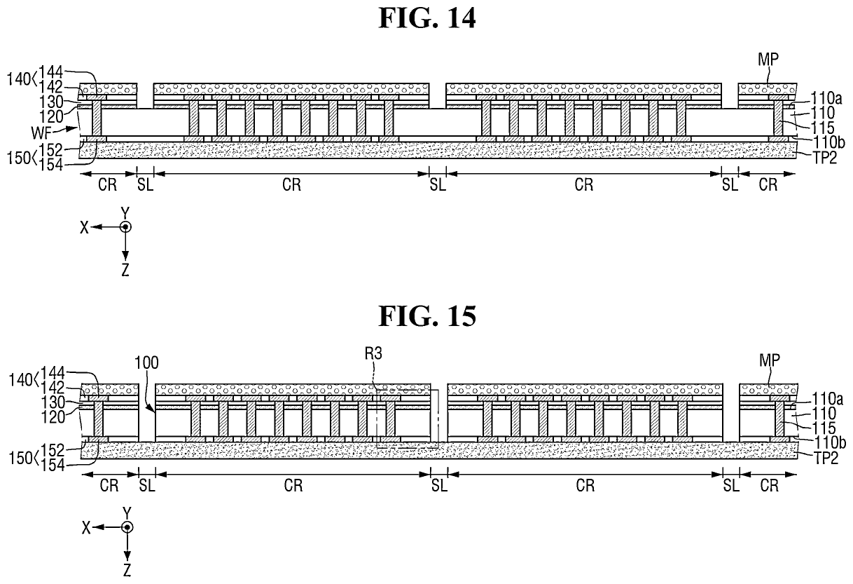

Referring to FIG. 14, according to one or more example embodiments, an etching process is performed on the first semiconductor device layer 120, the first chip wiring layer 130, the first front-side bonding layer 140, and the item patterns 160 using the mask patterns MP.

For example, a photolithography process using the mask patterns MP as an etching mask may be performed. As a result, the first semiconductor device layer 120, the first chip wiring layer 130, the first front-side bonding layer 140, and the item patterns 160 may be removed from the scribe lane regions SL.

The photolithography process may be used to remove the first semiconductor device layer 120, the first chip wiring layer 130, the first front-side bonding layer 140, and the item patterns 160 from the scribe lane regions SL, but one or more example embodiments are not limited thereto. Alternatively, according to one or more example embodiments, a laser grooving process and/or a blade grooving process may also be performed to remove the first semiconductor device layer 120, the first chip wiring layer 130, the first front-side bonding layer 140, and the item patterns 160 from the scribe lane regions SL.

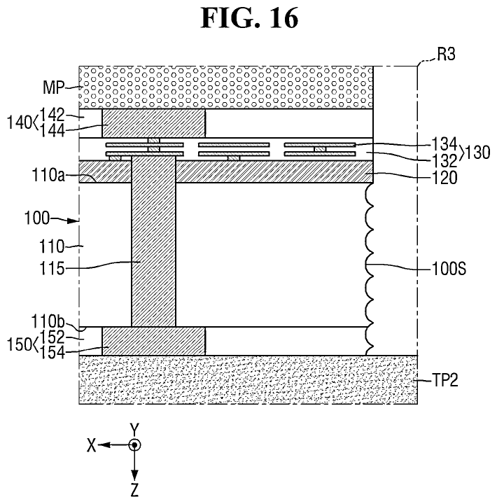

Referring to FIGS. 15 and 16, according to one or more example embodiments, a plasma dicing process is performed on the wafer WF. FIG. 16 is an enlarged cross-sectional view of region R3 of FIG. 15, according to one or more example embodiments.

As a result of the plasma dicing process, a plurality of first semiconductor chips 100 may be singulated from the wafer WF. Additionally, sides of the first semiconductor chips 100 may include a plurality of first recesses 100S. For example, deep reactive ion etching (DRIE) using the Bosch process may be performed. As a result of the Bosch process, which is a process for forming a high aspect ratio profile in Si by repeatedly performing isotropic and anisotropic etching, a plurality of first recesses 100S that form a repetitive scalloped surface on each of the sides of the first semiconductor substrate 110 may be provided.

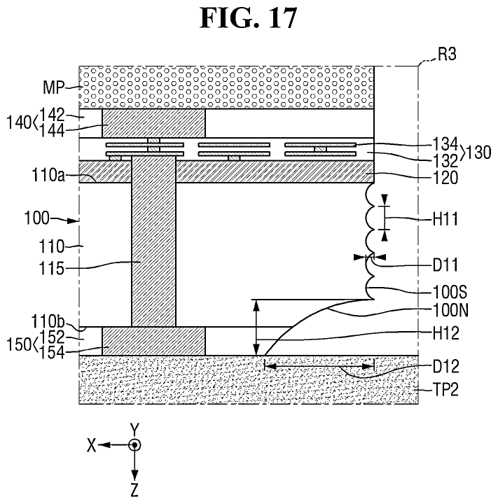

Referring to FIG. 17, according to one or more example embodiments, an over-etching process is performed on the bottoms of the first semiconductor chips 100.

As a result of the over-etching process, the first semiconductor chips 100 with second recesses 100N may be provided. For example, after the singulation of the first semiconductor chips 100 and the exposure of the second tape TP2, the plasma dicing process may be continued. According to one or more example embodiments, the etchant used in the plasma dicing process may be concentrated relatively on the exposed second tape TP2, thereby forming second recesses 100N at the bottoms of the first semiconductor chips 100 (e.g., at the bottom of the first back-side bonding layer 150 and/or the bottom of the first semiconductor substrate 110), which are larger in size than the first recesses 100S.

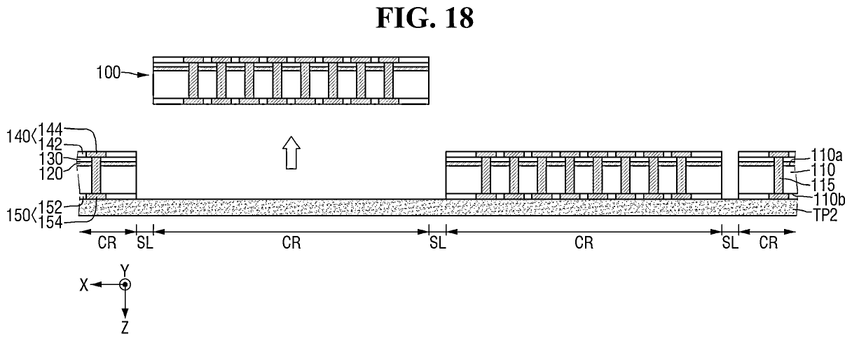

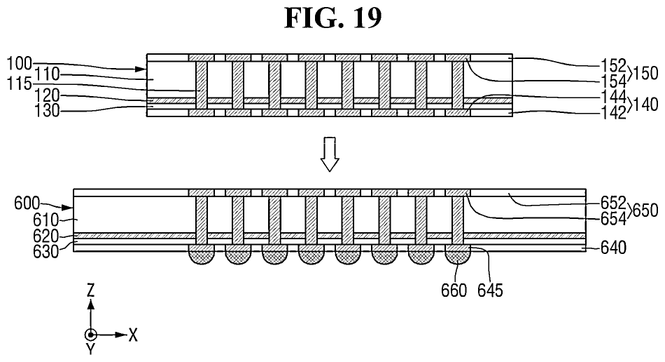

Referring to FIG. 18, according to one or more example embodiments, the first semiconductor chips 100 are separated from the second tape TP2.

Referring to FIG. 19, according to one or more example embodiments, the first semiconductor chips 100 are bonded onto first lower semiconductor chips 600 using the hybrid bonding method.

Thereafter, referring again to FIG. 1, second, third, fourth, and fifth semiconductor chips 200, 300, 400, and 500 are sequentially bonded onto each of the first semiconductor chips 100, and a first molding film 700 is formed. The bonding of the second, third, fourth, and fifth semiconductor chips 200, 300, 400, and 500 may be similar to the bonding of each of the first semiconductor chips 100, and thus, a duplicate detailed description thereof will be omitted. In this manner, the semiconductor package described above with reference to FIGS. 1 and 2 can be provided according to one or more example embodiments.

While example embodiments have been particularly shown and described above, it will be apparent to those of ordinary skill in the art that various changes in form and details may be made therein without departing from the spirit and scope of the following claims.

What is claimed is:

1. A semiconductor package comprising:
a first semiconductor chip comprising:
a first semiconductor substrate comprising a first front side and a first back side that is opposite to the first front side; and
a first back-side bonding layer comprising a first back-side bonding insulating film on the first back side, and a first back-side bonding pad within the first back-side bonding insulating film; and
a second semiconductor chip on the first semiconductor chip, the second semiconductor chip comprising:
a second semiconductor substrate comprising a second front side that faces the first back side, and a second back side that is opposite to the second front side,
a second front-side bonding layer comprising a second front-side bonding insulating film on the second front side and bonded to the first back-side bonding insulating film, and a second front-side bonding pad within the second front-side bonding insulating film and bonded to the first back-side bonding pad, wherein a side of the first semiconductor chip comprises:
a plurality of first recesses, which are arranged along a vertical direction that intersects the first front side and the first back side; and
a second recess, which partially exposes a bottom surface of the second front-side bonding layer, the second recess being provided between the second front-side bonding layer and the first recesses, and
wherein a depth of the second recess is greater than a depth of each of the first recesses in a first horizontal direction that intersects the side of the first semiconductor chip.

2. The semiconductor package of claim 1, wherein each of the first recesses and the second recess extends in a second horizontal direction that intersects the first horizontal direction.

3. The semiconductor package of claim 1, wherein each of the first recesses comprises a concave surface extending toward an interior of the first semiconductor substrate.

4. The semiconductor package of claim 1, wherein a height of the second recess is greater than a height of each of the first recesses in the vertical direction.

5. The semiconductor package of claim 1, wherein an external angle formed by a top surface of the first back-side bonding layer and the second recess is an acute angle at an interface between the first back-side bonding layer and the second front-side bonding layer.

6. The semiconductor package of claim 1, wherein the first semiconductor chip further comprises a first semiconductor device layer on the first front side, and
wherein each of the first recesses and the second recess is more recessed in the first horizontal direction than a side of the first semiconductor device layer.

7. The semiconductor package of claim 1, wherein the first semiconductor chip further comprises:
a first front-side bonding layer comprising:
a first front-side bonding insulating film on the first front side; and
a first front-side bonding pad within the first front-side bonding insulating film; and
a first through via penetrating the first semiconductor substrate and electrically connecting the first front-side bonding pad and the first back-side bonding pad.

8. The semiconductor package of claim 1, wherein the second semiconductor chip further comprises:
a second back-side bonding layer comprising:
a second back-side bonding insulating film on the second back side; and
a second back-side bonding pad within the second back-side bonding insulating film; and
a second through via penetrating the second semiconductor substrate and electrically connecting the second front-side bonding pad and the second back-side bonding pad.

9. The semiconductor package of claim 8, wherein a side of the second semiconductor chip comprises:
a plurality of third recesses, which are arranged along the vertical direction; and
a fourth recess, which extends from a top surface of the second back-side bonding layer and the plurality of third recesses, and
wherein a depth of the fourth recess is greater than a depth of each of the third recesses in the first horizontal direction.

10. A semiconductor package comprising:
a semiconductor substrate comprising a front side and a back side that is opposite to the front side;
a semiconductor device layer on the front side of the semiconductor substrate;
a chip wiring layer comprising:
an inter-wiring insulating film, which covers the semiconductor device layer; and
wiring structures within the inter-wiring insulating film and electrically connected to the semiconductor device layer;
a front-side bonding layer comprising:
a front-side bonding insulating film covering the chip wiring layer; and
a front-side bonding pad within the front-side bonding insulating film and electrically connected to the wiring structures;
a back-side bonding layer comprising:
a back-side bonding insulating film on the back side of the semiconductor substrate; and
a back-side bonding pad within the back-side bonding insulating film; and
a through via penetrating the semiconductor substrate and the semiconductor device layer, and electrically connecting the front-side bonding pad and the back-side bonding pad,
wherein a side of the semiconductor substrate comprises a plurality of first recesses arranged along a vertical direction that intersects the front side and the back side,
wherein a side of the back-side bonding layer comprises a second recess between a top surface of the back-side bonding layer and the plurality of first recesses, and
wherein a size of the second recess is greater than a size of each of the first recesses.

11. The semiconductor package of claim 10, wherein each of the first recesses and the second recess is more recessed in a first horizontal direction than each of a side of the semiconductor device layer, a side of the chip wiring layer, and a side of the front-side bonding layer.

12. The semiconductor package of claim 11, wherein the side of the semiconductor device layer, the side of the chip wiring layer, and the side of the front-side bonding layer are coplanar.

13. The semiconductor package of claim 10, wherein each of the first recesses comprises a concave surface extending toward an interior of the semiconductor substrate.

14. The semiconductor package of claim 10, wherein an external angle formed by a line extending collinear with the top surface of the back-side bonding layer and the second recess is an acute angle.

15. The semiconductor package of claim 10, wherein a slope of the second recess decreases as the second recess extends away from the top surface of the back-side bonding layer.

16. The semiconductor package of claim 10, wherein a ratio of a depth of the second recess in a first horizontal direction to a height of the second recess in the vertical direction is 0.05 to 0.2.

17. The semiconductor package of claim 10, wherein the second recess extends across the side of the back-side bonding layer and a side of the semiconductor substrate.

18. A semiconductor package comprising:
a lower semiconductor chip; and
a plurality of semiconductor chips sequentially provided on the lower semiconductor chip,
wherein each of the plurality of semiconductor chips comprises:
a semiconductor substrate comprising a front side facing the lower semiconductor chip, and a back side that is opposite to the front side;
a semiconductor device layer on the front side of the semiconductor substrate;
a chip wiring layer on the semiconductor device layer;
a front-side bonding layer comprising:
a front-side bonding insulating film on the chip wiring layer; and
a front-side bonding pad within the front-side bonding insulating film;
a back-side bonding layer comprising:
a back-side bonding insulating film on the back side of the semiconductor substrate; and
a back-side bonding pad within the back-side bonding insulating film; and
a through via penetrating the semiconductor substrate and electrically
connecting the front-side bonding pad and the back-side bonding pad, wherein a side of each of the plurality of semiconductor chips comprises:
a plurality of first recesses arranged along a vertical direction that intersects the front side and the back side; and
a second recess between a top surface of the back-side bonding layer and the plurality of first recesses, and
wherein a size of the second recess is greater than a size of each of the first recesses.

19. The semiconductor package of claim 18, wherein the lower semiconductor chip comprises a buffer chip, and
wherein each of the plurality of semiconductor chips comprises a memory chip.

20. The semiconductor package of claim 18, wherein the plurality of semiconductor chips are hybrid-bonded to one another.
